(19) United States
(12) Patent Application Publication
(10) Pub. No.: US 2026/0080139 A1
(43) Pub. Date: Mar. 19, 2026

(54) GENERALIZED PLACEMENT RETIMING FOR AN INTEGRATED CIRCUIT DESIGN

(71) Applicant: International Business Machines Corporation, Armonk, NY (US)

(72) Inventors: Jason Raymond Baumgartner, Austin, TX (US); Bradley Donald Bingham, Austin, TX (US); Robert Lowell Kanzelman, Rochester, MN (US); Raj Kumar Gajavelly, Bangalore (IN)

(73) Assignee: International Business Machines Corporation, Armonk, NY (US)

(21) Appl. No.: 18/885,708

(22) Filed: Sep. 15, 2024

(51) Int. Cl. G06F 30/3315; G06F 30/337

(52) U.S. Cl. CPC G06F 30/3315; G06F 30/337

(57) ABSTRACT

A technique of min-cut based retiming of a netlist includes forming a min-cut based retiming graph based on a netlist of a circuit design. Forming the min-cut based retiming graph includes refraining from use of reverse edges in at least some regions of the min-cut based retiming graph. The technique further includes computing a min-cut of the circuit design based on the min-cut based retiming graph, where the min-cut crosses at least one graph path multiple times in a particular region of the min-cut based retiming graph. Based on the min-cut, a behaviorally equivalent retimed netlist is then formed, including in the particular region.

### BACKGROUND OF THE INVENTION

The present invention relates in general to integrated circuit design, and more specifically, to retiming an integrated circuit design.

Retiming is a well-known integrated circuit (IC) design optimization technique used to reduce the number of state-holding elements (e.g., flip-flops, latches, or registers) in a netlist and/or to reduce combinational path latency by relocating state-holding elements across combinational gates. Reducing register count (so-called “min-area retiming”) is useful in both the design and synthesis phases of design, enabling power and area reductions. Min-area retiming is also useful in the verification phase of design. Many verification algorithms suffer run-time degradation proportional to register count, potentially exponentially so. Equivalence checking can also benefit from ability to convert a sequential netlist into a more canonical form, independent of original topology. This capability itself can trivialize some sequential equivalence checking problems.

Reducing combinational path latency (so-called “min-delay retiming”) is useful in both the design and synthesis phases of IC design to enable higher clock frequencies. Practically, in the design and synthesis phases, it is often desirable to achieve a balance between area and delay (so-called “delay-constrained min-area retiming”) to obtain a min-area retiming that does not violate the desired clock frequency.

Various algorithms have been proposed to solve the min-area retiming problem, including Integer Linear Program (ILP) solvers and a modified min-cut, max-flow algorithm. These algorithms all have super-linear run-time, and thus can consume minutes to several hours on very large netlists. Constrained min-area retiming can often be implemented by augmenting the min-area retiming package with additional constraints reflecting delay information. Practically, min-cut retiming tends to be far superior due to numerous benefits. For example, min-cut retiming is typically faster and can yield useful improvements even if time-constrained before finding a globally optimal solution. Min-cut retiming also yields a minimum-perturbation solution that moves as few registers to achieve an optimal netlist, whereas ILP yields an arbitrary optimal solution.

A retiming step either moves a register from each input net of a combinational gate onto its output nets or vice-versa. As such, the original netlist topology of combinational gates severely limits the set of possible retimed netlists. The literature has noted that iterating retiming with combinational logic transformations (“retiming and resynthesis”) can yield iterative, synergistic reductions even when applied with orthogonal optimization criterion. That is, retiming traditionally does not relocate registers specifically to benefit a subsequent combinational logic transformation, nor do traditional combinational logic transformations specifically try to enable better register placement by subsequent retiming. Such undirected iteration of transformations leaves room for improvement.

A specific type of intertwined technique of retiming and resynthesis has been proposed. In the proposed technique, an ILP-based retiming model can be adjusted to consider alternative 2-input decompositions of associative, commutative logic cones such as AND/OR/XOR/XNOR trees when seeking a superior retimed register placement. Once an optimal retiming solution is computed, these trees can be restructured accordingly, enabling a superior retimed netlist. No prior art has disclosed a way to achieve this benefit when using min-cut retiming.

Another limitation of min-cut retiming is that, at each iteration of the retiming process, exactly one retimed register will exist between an original register placement and next-state functions. This placement restriction also limits the set of possible retimed netlists, though departing from this scenario traditionally risks altering netlist behavior and thus is disallowed.

Given the broad value of retiming to the design, synthesis, and verification phases of integrated circuit design, a significant need remains for techniques that improve the quality of retiming results, for example, by yielding additional register reductions for min-area retiming.

### SUMMARY OF THE INVENTION

According to one or more embodiments, a technique of min-cut based retiming of a netlist includes forming a min-cut based retiming graph based on a netlist of a circuit design. Forming the min-cut based retiming graph includes refraining from use of reverse edges in at least some regions of the min-cut based retiming graph. The technique further includes computing a min-cut of the circuit design based on the min-cut based retiming graph, where the min-cut crosses at least one graph path multiple times in a particular region of the min-cut based retiming graph. A behaviorally equivalent retimed netlist is then formed based on the min-cut, including in the particular region. This technique, which can be implemented, for example, as a method, a computer program product, or a data processing system, provides the performance benefits of min-cut based retiming while avoiding formation of an invalid retimed netlist.

According to one or more embodiments, a technique of min-cut based retiming includes modeling an associative-commutative logic cone in a netlist as a single retiming graph node and suppressing reverse edges from the retiming graph node to its fanin gates. Based on placement of the min-cut at the retiming graph node, the behaviorally equivalent retimed netlist includes rewriting the associative-commutative logic cone into separate lagged and unlagged sub-functions and placing a retimed state-holding element between the lagged and unlagged sub-functions. This technique implements fanin register sharing with min-cut based retiming.

According to one or more embodiments, a technique of min-cut based retiming includes forming an associative-commutative logic cone modeled by a single retiming graph node to be of maximal fanout-free size. Prior to forming a min-cut based retiming graph, one or more state-holding elements partitioning two identical-function logic cones are backward retimed. This technique enables fewer and larger associative-commutative logic cones to be formed.

According to one or more embodiments, the min-cut based retiming graph includes no reverse edges outside associative-commutative logic cones. By restricting reverse edges in the retiming graph, this technique reduces the number of state-holding elements in the retimed netlist, by allowing a more generalized set of placements of state-holding elements than possible using traditional retiming techniques.

In one or more embodiments, forming a retimed netlist based on the min-cut includes creating replicated gates along paths of the min-cut based retiming graph that cross the min-cut more than once, placing a first retimed state-holding element at a topologically shallowest min-cut crossing, where the first retimed state-holding element corresponds to an original state-holding element in the netlist and the first retimed state-holding element sources a first copy of the replicated gates. A second copy of the replicated gates is sourced by a next-state function of the original state-holding element. Unlagged sinks are coupled to the first copy of the replicated gates, and lagged sinks are connected to a second retimed state-holding element placed at an output of the second copy of the replicated gates. This netlist retiming technique results in a valid (behaviorally equivalent) retimed netlist having equivalent function and fewer state-holding elements.

In one or more embodiments, a min-cut based retiming technique includes reducing a number of the replicated gates. Reducing the number of replicated gates includes identifying a fanout-free logic cone rooted at a topologically-deepest crossing of the min-cut, determining an alternative implementation of the fanout-free logic cone, where the alternative implementation includes a sub-function internal gate that dominates all unlagged inputs of the fanout-free logic cone and a minimum set of lagged inputs, replacing the fanout-free logic cone with the alternative implementation, and relocating the min-cut from an output of the fanout-free logic cone to the internal gate of the alternative implementation.

In one or more embodiments, prior to performing min-cut based retiming of the netlist, the netlist is rewritten to enlarge a size of a retimeable region in the netlist. Expanding the retimeable region enables elimination from the netlist of additional state-holding elements.

In one or more embodiments, a technique for rewriting a netlist to enlarge a size of a retimeable region of the netlist includes identifying a fanout-free logic cone including gates at a boundary between the retimeable region and an unretimeable region, determining, for the fanout-free logic cone, an equivalent alternative sub-function including as many leaves as possible from the retimeable region and no leaves from the unretimeable region, and, responsive to the sub-function including more leaves in the retimeable region than the fanout-free logic cone, rewriting the netlist to include the sub-function. This technique enables the boundary of the retimeable region to be expanded efficiently.

In one or more embodiments, after rewriting the netlist to enlarge the size of a retimeable region, min-cut based retiming of the netlist is performed. Rewriting the netlist to enlarge the retimeable region prior to retiming the netlist allows the min-cut based retiming to operate on a greater portion of the netlist, resulting in greater reductions in state-holding elements.

### BRIEF DESCRIPTION OF THE DRAWINGS

FIG. 1 is a high-level block diagram of an exemplary data processing environment in accordance with one or more embodiments;

FIG. 2 is a high-level logical flowchart of an integrated circuit design, verification, and fabrication process in accordance with one or more embodiments;

FIG. 3 is an exemplary portion of a netlist that illustrates forward and backward retiming;

FIG. 4 is an exemplary netlist that can be improved through min-cut retiming in accordance with one or more embodiments;

FIG. 5 illustrates a min-cut retiming of the exemplary circuit netlist of FIG. 4 that yields an invalid retimed netlist;

FIG. 6 depicts an exemplary netlist that exhibits fanout register sharing;

FIG. 7 illustrates an exemplary retiming of a netlist to obtain a retimed netlist exhibiting fanin register sharing;

FIG. 8 is a high-level logical flowchart of an exemplary technique of fanin register sharing using min-cut-based retiming in accordance with one or more embodiments;

FIG. 9 is illustrated a more detailed logical flowchart of an exemplary technique for identifying maximally sized fanout free trees in a netlist to be retimed in accordance with one or more embodiments;

FIG. 10 depicts a min-cut retiming of the exemplary circuit netlist of FIG. 4 that yields a valid retimed netlist in accordance with one or more embodiments;

FIG. 11 is a high-level logical flowchart of an exemplary technique of min-cut based retiming that achieves a generalized register retiming in accordance with one or more embodiments;

FIG. 12 is a high-level logical flowchart of an exemplary technique of forming a retimed netlist in accordance with one or more embodiments;

FIG. 13 is a high-level logical flowchart of an exemplary technique of minimizing gate duplication during generalized placement retiming in accordance with one or more embodiments;

FIG. 14 is a high-level logical flowchart of an exemplary technique of attempting to rewrite a maximally sized fanout-free logic cone in accordance with one or more embodiments; and

FIG. 15 is a high-level logical flowchart of an exemplary technique for rewriting a netlist to maximize the size of retimeable regions in accordance with one or more embodiments.

In accordance with common practice, various features illustrated in the drawings may not be drawn to scale. Accordingly, dimensions of the various features may be arbitrarily expanded or reduced for clarity. In addition, some of the drawings may not depict all of the components of a given system, method, or device. Finally, like reference numerals may be used to denote like or corresponding features in the specification and figures.

### DETAILED DESCRIPTION OF ILLUSTRATIVE EMBODIMENT

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

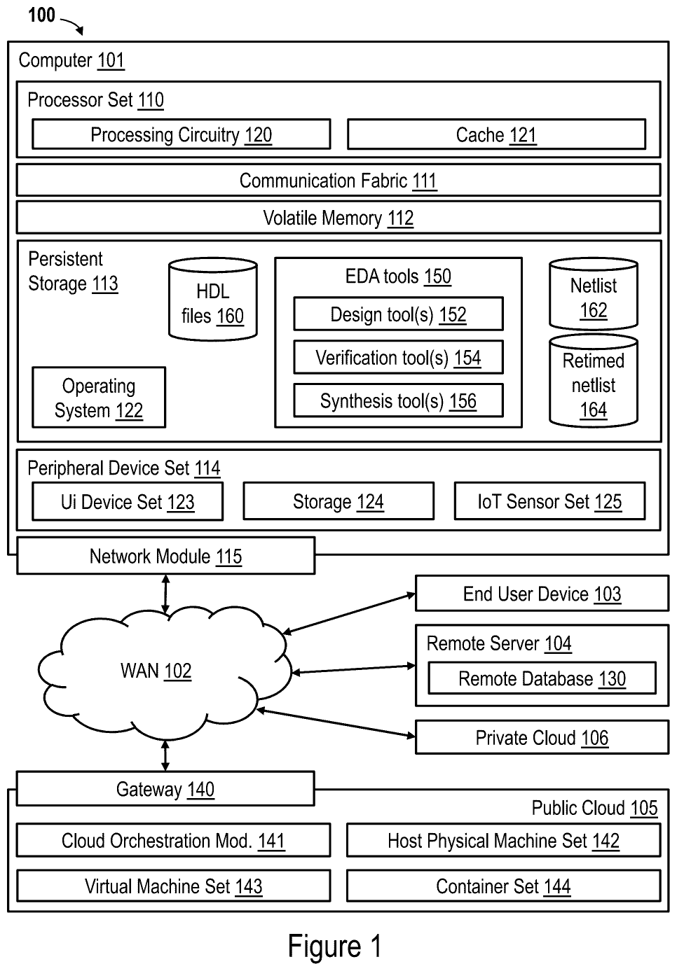

With reference now to FIG. 1, computing environment 100 contains an example of an environment for the execution of at least some of the computer code, such as electronic design automation (EDA) tools 150, involved in performing the inventive methods. In addition, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and other code and data), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one or more computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be implemented in EDA tools 150 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet-of-Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the Internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the Internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Those of ordinary skill in the art will appreciate that the architecture and components of a data processing environment can vary between embodiments. Accordingly, the exemplary computing environment 100 given in FIG. 1 is not meant to imply architectural limitations with respect to the claimed invention.

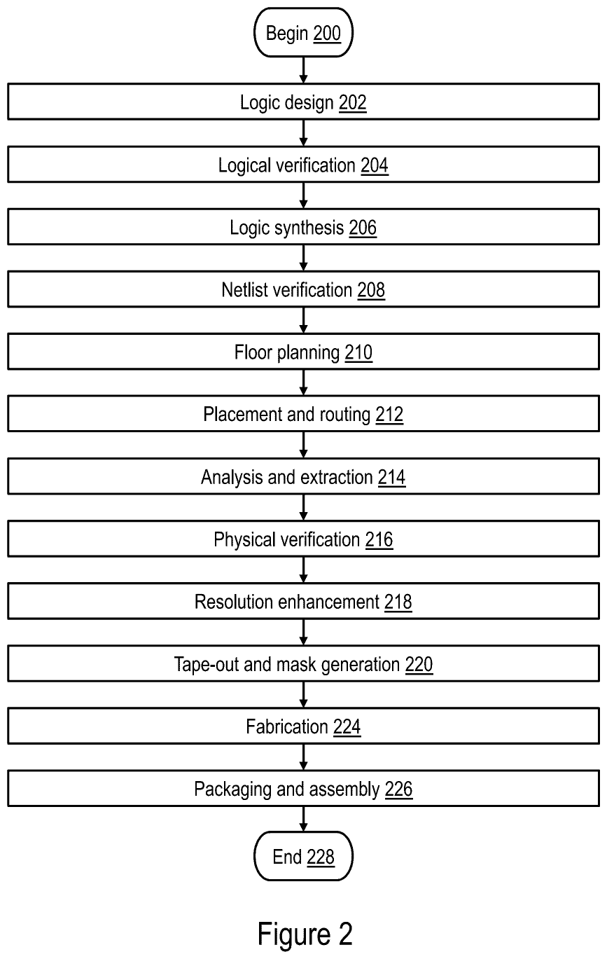

Referring now to FIG. 2, there is depicted a high-level logical flowchart of an integrated circuit design, verification, and fabrication process in accordance with one or more embodiments. The depicted process may be performed, in part, through the use of EDA tools 150, which may include, for example, design tool(s) 152, verification tool(s) 154, and synthesis tool(s) 156. Those skilled in the art will appreciate that many of the steps of the depicted process can be performed contemporaneously and/or in a different order than illustrated, and further, may be performed iteratively. It will also be appreciated that for large-scale designs, it is typical for the overall design to be decomposed into multiple smaller units or entities, for which many of the illustrated steps can be separately performed. In the industry, it is also common for multiple parties to separately perform at least some of the illustrated steps and combine the separate work of the multiple parties through inter-party licensing of intellectual property (IP) blocks and/or contract manufacturing.

The process of FIG. 2 begins at block 200 and then proceeds to bock 202, which illustrates a logic design step 202. In step 202, human and/or automated (e.g., artificial intelligence (AI)) circuit designer(s) may specify an initial design for an integrated circuit using one or more design tool(s) 152. The specification for the integrated circuit may be expressed, for example, within hardware description language (HDL) files 160 utilizing a HDL such as Very High Speed Integrated Circuit Hardware Description Language (VHDL), Verilog, SystemVerilog, SystemC, MyHDL or OpenVera. Those skilled in the art will appreciate that EDA tools 150 may transform the HDL description into one or more lower level design description such as a logic-level RTL description, a gate-level description, a layout-level description, or a mask-level description. Each succeeding lower level of design representation provides more specific details for a particular integrated circuit implementation of the design. During logic design step 202, the design can be decomposed into different entities or units to facilitate parallelization of the design effort and modular processing at subsequent design steps.

After a specification of the logical design is developed at logic design step 202, one or more verification tool(s) 154 are executed to verify the logical correctness of the logic design at logical verification step 204. The verification tool(s) 154 may include, for example, simulators, testbench generators, static HDL checkers, and formal verification tools. Synthesis tool(s) 156 can additionally be executed to transform the logic design represented in HDL files 160 into a netlist 162 in a logic synthesis step 206.

In a typical implementation, a netlist is a directed graph including a plurality of nodes representing “gates” and a plurality of edges representing “wires” (or “nets” or “signals”) between the gates. Gates have associated functions, such as constants, primary inputs, combinational logic (e.g., AND, OR, etc.) and sequential elements (e.g., latches or registers). Hereafter, all sequential elements are referred to as “registers” for brevity. Certain gates are labeled as “primary outputs” of the netlist, which along with primary inputs represent interconnections to other logic components. Logic synthesis step 206 generally must preserve the behavior of primary outputs relative to primary inputs.

Generally, a netlist 162 can support arbitrary gate types with an arbitrary number of input and output pins. However, in some exemplary embodiments, netlist 162 is an AND/Inverter graph in which combinational gates are implemented with simple two-input AND gates, and inversions are implicit attributes of edges. In some cases, different netlist formats are utilized in different steps or stages of the integrated circuit design process. For example, integrated device manufacturer (IDM) netlist can be used in logic synthesis step 206, and a Design Activity Database (DADB) netlist can be used in the netlist verification step 208 (discussed below). Typically, each different netlist format supports a respective fixed set of gate types. Typically, in a design-compilation flow for synthesis or for verification, netlists begin with higher-level gates (e.g., vectored multiplexors and adders). Subsequently, during compilation/model-build flow, the netlist gates are gradually decomposed into smaller, simpler gates, allowing fine-grained optimizations.

In a netlist, a “fanout-free logic cone” relative to a set of root gates R is a set of gates F which are topologically dominated by those root gates, that is, every path from any gate in F to next-state functions or primary outputs passes through R. Herein, gates at the input of the fanout-free logic cone are referred to as “leaves,” which can be arbitrary gates instead of “primary inputs” of the netlist. In the following description, aspects of the disclosed inventions rely upon identifying fanout-free logic cones relative to a single root gate.

Following step logic synthesis step 206, EDA tools 150 can be executed to perform a netlist verification step 208. In netlist verification, EDA tools 150 verify compliance of the netlist for correspondence to the design specified by the HDL files 160 and for compliance with any timing constraints of the design.

EDA tools 150 can then be executed to develop an implementation of the design as a physical integrated circuit. The development of the integrated circuit can begin with a floor planning step 210 in which a basic floor plan for the units and routing for the integrated circuit is constructed. Developing on the high-level physical layout provided by the floor plan, a more detailed physical layout is developed in placement and routing step 212. In step 212, standard cells, individual circuit components (e.g., transistors and capacitors), and routing are physically placed within the integrated circuit floorplan.

EDA tools 150 can additionally be executed to validate circuit function in an analysis and extraction step 214. In physical verification step 216, EDA tools 150 also verify satisfaction of manufacturing constraints, such as design rule check (DRC) constraints, power constraints, lithography constraints, etc., and further check that the integrated circuit conforms to the HDL design specification. EDA tools 150 further improve the geometry of the physical layout for purpose of manufacturing in a resolution enhancement step 218. Based on the final geometry determined at step 218, EDA tools 150 can generate, in tape-out and mask generation step 220, data sets detailing the design for lithographic masks utilized to fabricate the integrated circuit.

Following tape-out and mask generation step 220, lithographic masks can be utilized to fabricate integrated circuit chips in fabrication step 224. These integrated circuit chips can then be packaged and assembled on circuit cards and/or circuit boards, as depicted in packaging and assembly step 226. Thereafter, the process of FIG. 2 ends at block 228.

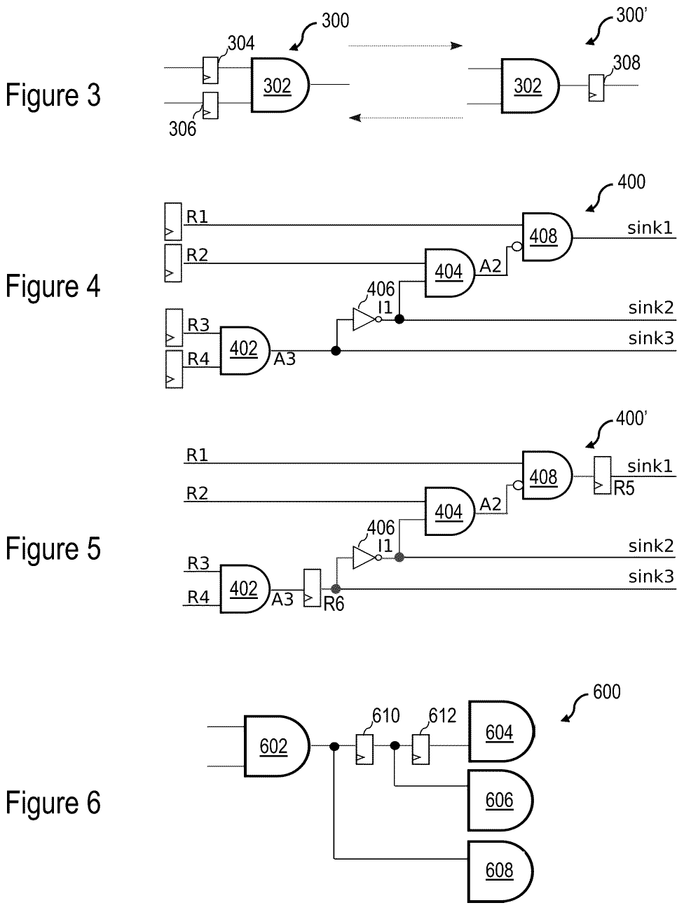

The inventions disclosed herein, which may be implemented in one or more EDA tools 150, relate to retiming netlists, such as a netlist 162. As shown in FIG. 3, “retiming” refers to relocating registers with respect to a combinational gate. Retiming can be characterized with respect to a combinational gate as either forward retiming (or “negative lagging”) in which registers are moved from all inputs of a combinational gate to its outputs or as backward retiming (or “positive lagging”) in which registers are moved from all outputs of a gate to its inputs. Thus, in forward retiming of a netlist 300 including AND gate 302, registers 304 and 306 at the inputs of AND gate 302 are replaced by a register 308 at the output of AND gate 302 in netlist 300′. Conversely, in negative retiming of AND gate 302 of netlist 300′, register 308 at the output of AND gate 302 is replaced by registers 304-306 at the inputs of AND gate 302 to obtain netlist 300. Forward retiming of a combinational gate is therefore only possible if a register is present at, or can be relocated to, each input of the combinational gate. Globally optimal retiming involves iteratively applying retiming steps across combinational gates until optimality is achieved for the entire netlist. Each original combinational gate correlates uniquely to a gate of the same function in the retimed netlist; only register placement is adjusted between the original netlist and the retimed netlist. In general, retiming is one of many design optimization techniques that can be employed, for example, in synthesis tool(s) 156, and can be used synergistically with other design optimization techniques.

At a high level, in order to retime a netlist, a directed “retiming graph” is created from a netlist graph, and a mapping from nodes (gates) in the input netlist to nodes in the retimed netlist is created. Then an arbitrary retiming algorithm, such as a min-cut algorithm or an Integer Linear Program (ILP), is used to compute an optimal retiming result on the retiming graph. Finally, when an optimal retiming result is available for the retiming graph, a retimed netlist is created using the retiming solution, mapped to the original netlist. For example, by analyzing which retiming graph nodes are lagged, the forward retiming applied to a register in the input netlist to arrive it its final optimal location in the retimed netlist can be calculated. Min-cut retiming has numerous benefits over ILP-based retiming. For example, min-cut retiming typically is significantly faster than ILP-based retiming and yields a minimum perturbation solution in which a minimal set of registers is moved to yield an optimal retimed netlist. ILP-based retiming can yield an arbitrary optimal solution, which might move more registers than necessary to achieve optimality. Min-cut retiming can yield useful reductions even if early terminated before global optimality due to resource limits or restriction of “maximum lag,” while ILP-based retiming may not produce a usable result if early terminated.

Turning now to min-cut retiming specifically, given a directed graph in which some nodes are labeled as sources and others are labeled as sinks, a “cut” of the directed graph partitions the nodes into two sets: the “source side” containing all sources and the “sink side” containing all sinks. Edges crossing from the source side to the sink side are referred to as “cut edges,” and source-side nodes connected to cut edges are referred to as “cut nodes.” A cut with a minimal number of cut nodes is called a “min-cut.” Many algorithms have been proposed to compute min-cuts of a graph. These min-cut algorithms attempt to push unitary flow from each source toward sinks. Edges have predefined capacity, typically unitary or infinite. When a unit of flow is pushed along a path from source to sink, unit-capacity edges are “saturated,” and no additional flow may be pushed through them. Once global optimality is achieved (i.e., a maximum amount of flow is pushed from sources to sinks), the source-side of the min-cut is computed as the set of nodes reachable from sources along unsaturated edges or by traversing saturated edges backward; the sink-side comprises the remaining unreachable nodes.

For min-cut based retiming, retiming-graph nodes are created to represent current register locations and are labeled as “source nodes.” Retiming-graph nodes, labeled as “sink nodes,” are also created for each register's next-state function and for each primary output of the netlist. Each combinational netlist gate is modeled as a node pair <receiver, emitter> in the retiming graph. Input edges to the combinational netlist gate become input edges to the receiver. An edge is added from the receiver to the emitter. Output edges from the gate become output edges from the emitter. By modeling receiver-to-emitter edges as “unit capacity” and all other edges as “infinite capacity”, when using any max-flow algorithm every min-cut will lie between the receiver and the emitter. This type of modeling is common when using min-cut analysis of netlists in EDA tools, such as EDA tools 150. The outputs of the resulting min-cut gates are used as the location of retimed registers, some of which may be unmoved original register locations. As such, each min-cut iteration lags gates by at most 1 cycle or latch clock period. If any registers are moved, a new retiming graph is created taking into account the resulting retimed netlist's register locations, and the process is repeated until global optimality is achieved, i.e., until retiming is unable to improve upon the existing netlist.

Hereafter, for brevity a number of retiming techniques are described with reference to forward retiming. The described techniques are also applicable to backward retiming by considering fanout-to-fanin instead of fanin-to-fanout edges and by replacing “sources” with “sinks” (i.e., by reversing the direction of the retiming graph). For brevity, all state-holding elements in a netlist are referred to herein as “registers.” The described techniques are also applicable to other types of state-holding elements, such as latches and flip-flops.

One complication of min-cut based retiming is that to yield a behaviorally equivalent netlist, the computed min-cut between sources and sinks must cross each path exactly once, whereas direct min-cut computation will yield a min-cut which crosses each path at least once. If the min-cut crosses a path from sources (original register outputs) to sinks (next-state functions) more than once, two retimed registers would be placed along that path, altering sequential latency and thus the behavior of the retimed netlist.

For example, FIG. 4 depicts an original netlist 400 to be retimed. Netlist 400 includes four sources to which a respective one of registers R1 to R4 is coupled. Registers R3 and R4 feed a two-input AND gate 402 having an output coupled to net A3, which is in turn coupled to sink sink3. Net A3 is further coupled via an inverter 406 to net I1, which is further coupled to sink sink2. Net I1 is additionally coupled to one input of two-input AND gate 404, which has another input coupled to register R2. The output of AND gate 404 is coupled by net A2 to an inverting input of two-input AND gate 408. AND gate 408 has a second input coupled to register R1 and has an output coupled to sink sink1. In this example, a direct min-cut computation between original registers R1 to R4 and sinks sink1 to sink3 lies at AND gates 402 and 408 driving net A3 and sink1. This direct min-cut crosses the path from registers R3 and R4 to net A3 to net I1 to A2 to sink1 twice and consequently does not result in a legal retiming. Specifically, as illustrated in retimed netlist 400′ of FIG. 5, sink sink1, which originally depended in FIG. 4 upon the values of next-state functions of registers R3 and R4 one clock later, depends on these values of the next-state functions of sources R3 and R4 two cycles later in retimed netlist 400′ due to the presence of register R5 inserted between AND gate 408 and sink sink1, which has another retimed register R6 at the output of AND gate 402 along the original netlist path from registers R3 and R4 to net A3 to net I1 to net A2. The insertion of this additional cycle of delay results in an invalid retimed netlist 400′.

In the prior art, one proposed solution to the invalid timing that can result from direct min-cut computation is to add infinite-capacity reverse edges from the receiver of each gate to the receiver of each input edge to that gate. Doing so allows more flow to be pushed through the resulting retiming graph, which generally results in a retimed netlist with more registers. This overhead suffices to ensure that the resulting min-cut crosses each path from sources to sinks exactly once. By adding reverse edges, an additional unit of flow can be pushed from A2 to I1, which would yield a min-cut at R1, R2, A3 and thereby a legal retiming. This conventional approach can thus reduce the register count from 4 to 3 in this example of FIG. 4. As discussed further below with reference to FIG. 11, the generalized placement retiming described herein can reduce the register count in the retimed netlist from 4 to 2, at the cost of some combinational gate duplication.

In prior art ILP and min-cut based retiming, “fanout register sharing” is commonly employed to allow a retimed register placed at the output of a gate to be shared by multiple fanouts of that gate. For example, FIG. 6 illustrates an exemplary netlist 600 including AND gates 602, 604, 606, and 608 and registers 610 and 612. In this example, two output edges from AND gate 602 (i.e., to AND gates 604 and 606) share register 610, but only the output edge to AND gate 604 samples register 612. Netlist 600 illustrates that different fanout gates may have different lags. The difference between the lag of a source gate and the lag of its sink gate represents the number of retimed registers injected along that edge in the retimed netlist.

In ILP-based retiming, fanout sharing is modeled by adding fabricated nodes and edges to the retiming graph and by adjusting edge-weights to be fractional. As a result, the collection of fanout-shared edges plus the fabricated edges precisely model the number of fanout-shared registers. This ILP modeling was extended to “fanin register sharing.” This modeling can be used for each 3-or-more-input fanout-free associative and commutative logic region, for example AND/OR/XOR/XNOR trees. The intuition is that such logic regions may be restructured as a sequence of nested 2-input gates, allowing retiming to place registers within these rewritten regions for more optimal retimed register count.

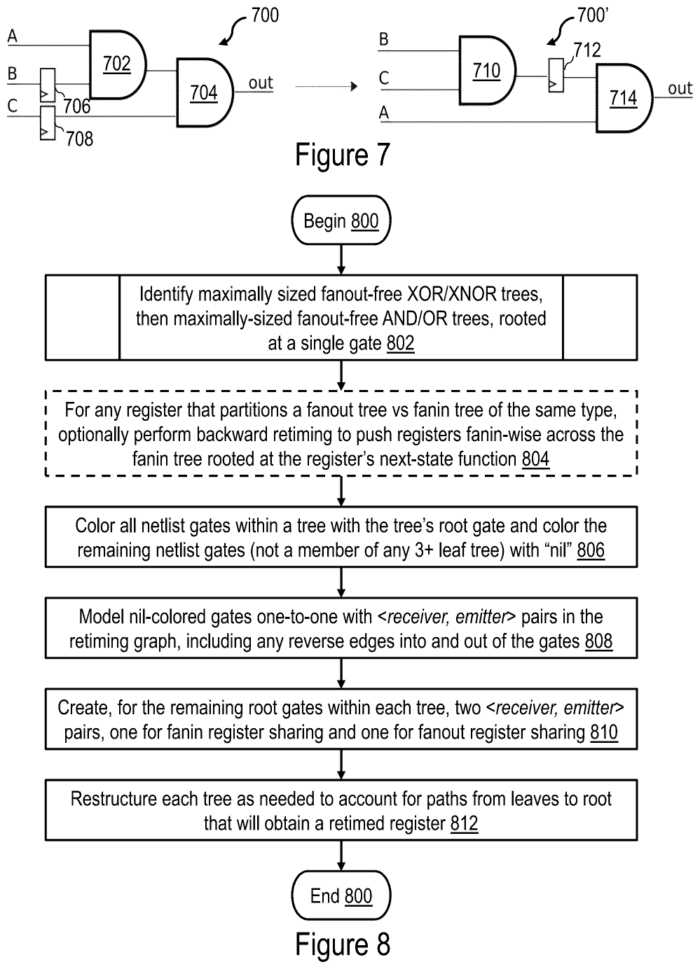

Referring now to FIG. 7, there is depicted an exemplary retiming of a netlist 700 to obtain a retimed netlist 700′ exhibiting fanin register sharing. As is evident, without restructuring the AND tree including AND gates 702, 704, no forward retiming is possible because edge A does not have an associated register. By restructuring the AND tree in retimed netlist 700′ with AND gates 710, 714, the original two registers 706, 708 at edges B and C, respectively, can be forward-retimed to form register 712, reducing the register count from 2 in original netlist 700 to 1 in retimed netlist 700′. The ILP modeling of fanin register sharing is identical though reversed from the modeling of fanout register sharing.

In min-cut based retiming, fanout register sharing is achieved natively by splitting each node in the retiming graph (correlating to a combinational netlist gate) into the <receiver, emitter> pair described above. The computed min-cut will always fall between receiver and emitter nodes, and the retimed netlist will place a retimed register at the output of the min-cut node's corresponding gate, which can be shared between multiple fanout edges. However, it is not necessary that every fanout edge sample the retimed register. Fanout edges that do not cross the min-cut are sourced by the min-cut gate instead of by the retimed register at its output.

Unlike conventional ILP-based modeling, prior art min-cut based retiming does not support fanin register sharing. However, in accordance with one aspect of the disclosed inventions, a technique for fanin register sharing with min-cut based retiming is disclosed.

Referring now to FIG. 8, there is depicted a high-level logical flowchart of an exemplary technique of fanin register sharing using min-cut-based retiming in accordance with one or more embodiments. The exemplary technique can be implemented, for example, through the execution by processing circuitry 120 of an EDA tool 150, such as one of synthesis tools 156.

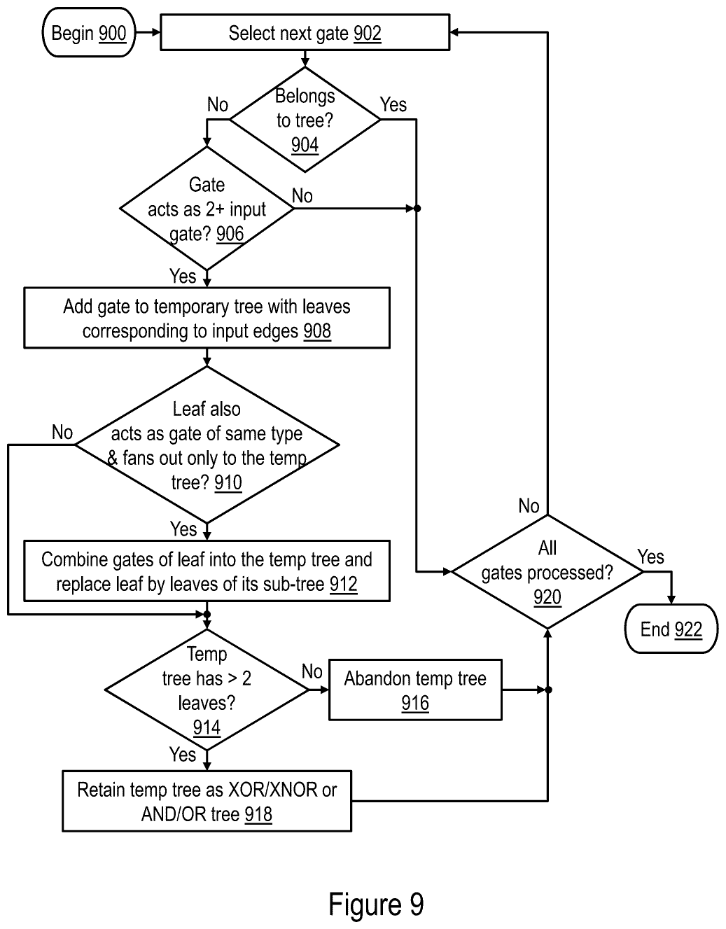

The process of FIG. 8 begins at block 800, for example, in response to an EDA tool 150 executing on processing circuitry 120 receiving an indication of a netlist 162 to be retimed. In various use cases or implementations, the netlist 162 to be retimed can be identified and indicated automatically by an EDA tool 150 or can be indicated by a human designer. The process proceeds from block 800 to block 802, which illustrates the processing circuitry 120 identifying the maximally sized fanout-free XOR/XNOR tree(s) and then the maximally sized fanout-free AND/OR tree(s) all rooted at each single gate. An exemplary process for identifying the maximally sized fanout-free XOR/XNOR tree(s) and AND/OR tree rooted at each gate is illustrated in FIG. 9, which is described below.

Processing circuitry 120 can optionally further preprocess the netlist 162 to enable formation of larger fanout-free trees (block 804). For example, at block 804, processing circuitry 120 can identify any register that partitions a fanout tree versus a fanin tree of the same type and perform backward retiming to push that register fanin-wise across the fanin tree rooted at the register's next-state function. As a consequence, a single bigger tree rooted the fanout tree's root can be formed.

At block 806, processing circuitry 120 classifies all gates in the netlist 162 as either a member of or not a member of a 3+ leaf tree. For example, in one embodiment, processing circuitry 120 “colors” (labels or tags) all gates that are members of a 3+ leaf tree with a tag or label identifying the tree's root gate. Processing circuitry 120 can also color any remaining netlist gate(s) not a member of a 3+ leaf tree with “nil.”

Block 808 illustrates that processing circuitry 120 explicitly models nil-colored gates one-to-one with <receiver, emitter> pairs in the retiming graph, including any reverse edges into and out of the nil-colored gates. No fanin register sharing is achieved for the nil-colored gates. However, fanin register sharing is possible for the remaining (not nil-colored) gates. As depicted at block 810, processing circuitry 120 creates, for each colored gate, two <receiver, emitter> pairs in the retiming graph: one pair for fanin register sharing and one pair for fanout register sharing. The fanin-register-sharing receiver-emitter pair has a single multi-input receiver node (one input per leaf) in the retiming graph, with the receiver node having a unit-capacity edge to its corresponding emitter node. This fanin-register-sharing emitter has a single infinite-capacity output edge to the fanout-register-sharing receiver, which has a unit-capacity edge to its corresponding fanout-register-sharing emitter. The fanout-register-sharing emitter, in turn, has an output edge to each fanout of the tree's root gate. Processing circuitry 120 adds to the retiming graph a single reverse edge from each fanout gate of the tree's root to its fanout-sharing node's receiver. Processing circuitry 120 preferably refrains from adding reverse edges from the tree's nodes to leaves, thereby allowing smaller min-cuts to model fanin register sharing. In at least some embodiments, the processing depicted at block 810 can be further optimized by omitting the fanout-register-sharing node if the tree's root gate has only one output, since no fanout register sharing is possible. In this case, the fanin-register-sharing emitter has an output edge to the fanout of the tree's root gate, and the reverse edges from fanout gates are added to the fanin-register-sharing receiver. It should be noted that a min-cut cannot include both the fanin-register-sharing node and the fanout-register-sharing node of a single tree due to the infinite-capacity edge between them.

At block 812, processing circuitry 120 restructures the trees in the retiming graph, as needed, to obtain the min-cut retimed netlist 164. In particular, processing circuitry 120 re-forms trees, as needed, to take into account the paths from leaves to root into which a retimed register is inserted. If the min-cut does not include the tree's fanin-register-sharing node, processing circuitry 120 need not restructure the tree to enable fanin register sharing, and the tree's nodes are either all lagged (in the source side of the min-cut) or all not lagged (in the sink side of the min-cut). If, on the other hand, the min-cut includes the tree's fanin-register-sharing node, processing circuitry 120 retimes leaf nodes on the source side of the min-cut forward, forms a sub-root in the retimed netlist 164 by creating a gate of the same type as the corresponding tree having the source-side leaf nodes as inputs, and places a retimed register at the output of this sub-root. Additionally, processing circuitry 120 creates a new gate of the same type, with sink-side leaves and the retimed register as input and replaces the original tree root gate in the retimed netlist 164 with the newly created gate.

The present disclosure thus discloses that fanin register sharing can be implemented in min-cut based retiming by modeling an associative-commutative logic cones in the netlist as a single retiming graph node and suppressing reverse edges from the retiming graph node to its fanin gates. If the min-cut includes the retiming graph node, formation of the behaviorally equivalent retimed netlist includes rewriting the associative-commutative logic cone into separate lagged and unlagged sub-functions and placing a retimed state-holding element between the lagged and unlagged sub-functions.

An example of the restructuring depicted at block 812 of FIG. 8 can be seen with reference again to FIG. 7. In FIG. 7, original netlist 700 includes two 2-input AND gates 702, 704, which can be combined into a single 3-leaf AND tree. In this example, it can be assumed that leaves B and C are driven by register outputs, and leaf A is driven from unillustrated fanin logic. Assuming leaf A lies in the sink-side of the cut (i.e., no register is forward-retimed across A), the min-cut will include the tree's fanin-register-sharing node. The source-side leaves will include leaves B and C. Thus, a sub-root AND is formed with leaves B and C as inputs, and the corresponding original registers 706, 708 at leaves B and C are forward-retimed to the output of this sub-root gate. Then processing circuitry 120 creates another AND gate 714 whose input is this retimed register and the sink-side leaf A. Note that if reverse edges were added from the tree root to leaf nodes, this would undermine the register reductions possible by fanin register sharing because those reverse edges would force the tree root to be on the same side of the min-cut as the leaves.

With reference FIG. 9, there is illustrated a more detailed logical flowchart of an exemplary technique for identifying maximally sized fanout free trees in a netlist to be retimed in accordance with one or more embodiments. Processing circuitry 120 can perform the process depicted in FIG. 9, for example, at block 802 of FIG. 8.

The process of FIG. 9 begins at block 900 and then proceeds to block 902, which illustrates processing circuitry 120 selecting a next gate in the netlist 162 to be retimed. At block 904, processing circuitry 120 determines whether or not the gate selected at block 902 already belongs to a fanout-free XOR/XNOR or fanout free AND/OR tree. In response to an affirmative determination at block 904, the process passes to block 920, which is described below.

In response to a determination that the selected gate does not belong to fanout-free XOR/XNOR or AND/OR tree, processing circuitry 120 additionally determines at block 906 whether the selected gate acts as agate having two or more inputs. At block 906, processing circuitry 120 makes an affirmative determination based on the selected gate being an XOR, XNOR, AND, or OR gate. If the selected gate is one of these gate types, processing circuitry 120 also makes an affirmative determination at block 906 if the immediate fanin of the selected gate causes the selected gate to serve as a different gate type. For example, in an AND/Inverter graph netlist in which all gates are 2-input AND gates, a local check is performed of whether a gate's two inputs are both driven by AND gates and the gates collectively implement either ((a & !b)∥(!a & b)) or (!(a & b)∥!(!a & !b)) where a and b are arbitrary edges with “inversion attributes” in the netlist graph. If so, the collection of 2-input AND gates collectively serve as an XOR gate or XNOR gate (depending upon how many inversion attributes were present to map into this form), and the root node is a candidate for an XOR/XNOR tree.

In response to a negative determination at block 906, the process passes to block 920, which is described below. If, however, processing circuitry 120 makes an affirmative determination at block 906, processing circuitry 120 creates a temporary tree of the relevant type (e.g., XOR, XNOR, AND or OR) with leaves corresponding to input edges (e.g., edges a and b in the above example) (block 908). The process proceeds from block 908 to block 910, which illustrates processing circuitry 120 checking whether or not each leaf of the temporary tree formed at block 908 also acts as a gate of the relevant type (e.g., XOR, XNOR, AND or OR) and fans out only to the temporary tree. If processing circuitry 120 makes an affirmative determination at block 910, processing circuitry 120 combines the gates of the leaf into the temporary tree and replaces the leaf by the leaves of its sub-tree (block 912). It should be noted that if any leaf of a temporary tree has two or more fanouts not dominated by the temporary tree's root, processing circuitry 120 will not combine that internal node into the fanout temporary tree and instead retains the leaf of the temporary tree (which may be considered its own independent tree).

The process of FIG. 9 passes to block 914 from block 912 or based on a negative determination at block 910. Block 914 illustrates processing circuitry 120 determining whether or not the temporary tree formed at block 908 includes more than 2 leaves. Processing circuitry 120 abandons temporary trees with only 2 leaves because these temporary trees cannot be restructured to allow fanin-register sharing (block 916). However, processing circuitry 120 retains any temporary trees having three or more leaves as a maximally sized fanout-free tree of the relevant type (block 918). Each of such fanout-free trees can be implemented using two or more netlist gates, and has a set of leaves corresponding to the source nodes of input edges to the fanin-most gates within the tree. For example, in FIG. 7, the AND gates 710 and 714 form a single 3-leaf AND tree rooted at “out” because no intermediate different-function gate or inverter is interposed between them. This AND tree has leaves at net A and the registers at nets B and C. Following block 916 or block 918, the process proceeds to block 920, which illustrates processing circuitry 120 determining whether or not all gates in the netlist 162 have been processed. If not, the process returns to block 902 and following blocks, which have been described. If, however, processing circuitry 120 determines at block 920 that all gates of the netlist 162 have been processed by the process of FIG. 9, the process of FIG. 9 ends at block 922.

Referring again briefly to FIG. 3, a single retiming step moves a register from each input of a gate to its output or vice-versa. Aside from fanout register sharing and fanin register sharing, retiming is limited to performing these primitive steps in an attempt to find a globally optimal register placement. Resynthesis may also be independently performed to alter combinational gates, and retiming can be applied before and after resynthesis to yield additional synergistic netlist improvements. However, aside from fanin register sharing, retiming and resynthesis typically have independent optimality criteria.

As discussed above with reference to FIG. 4, min-cut based retiming requires the retiming graph be augmented with reverse edges so that the resulting min-cut crosses each path from original register location to next-state functions exactly once. Otherwise, as noted above, sequential latency of a path would be altered, resulting in an invalid retimed netlist having a different behavior than the original netlist (as discussed above with reference to FIG. 5). The reverse edges increase the amount of flow that can be pushed from sources to sinks and thus generally increase the number of registers in the retimed netlist. Fanin register sharing as discussed with reference to FIGS. 8 and 9 provides a technique to improve retimed netlist optimality by selectively suppressing certain reverse edges within associative commutative logic trees, restructuring them as necessary to implement a valid retimed netlist.

The present disclosure appreciates that a retimed netlist can be generated with fewer registers and more general register placement than is possible with traditional min-cut based or ILP-based retiming, even if augmented with fanin register sharing and fanout register sharing. In one or more embodiments, a technique of min-cut based retiming can allow this reduction in the number of registers in the retimed netlist to be achieved without insertion of reverse edges, enabling smaller min-cuts than possible in the prior art. As discussed in more detail below, one technical aspect of the disclosed technique is generating a behaviorally equivalent retimed netlist in cases in which the min-cut crosses a path of the retiming graph multiple times.

With fanout register sharing, not every fanout edge of a retimed register needs to be sourced by the retimed register; those that do not cross the min-cut may be sourced by the next-state function of the retimed register (i.e., the min-cut gate itself) rather than the retimed register placed at the output of the min-cut gate. The disclosed technique of generalized placement retiming generalizes this concept from fanout register sharing by replicating certain combinational gates between paths that cross the min-cut more than once, enabling some sinks to refer to retimed register outputs and other sinks to refer to retimed register next-state functions. In FIG. 4, without reverse edges, a min-cut would include the source of net A3 and sink sink1. This min-cut would place a retimed register at the source edge of net A3 and at sink sink1 as depicted in FIG. 5. As noted previously, this register placement would be illegal in conventional min-cut based retiming because the path from nets R3 and R4 to net A3 to net I1 to net A2 to sink1 crosses the min-cut twice and has a sequential latency of 2 cycles (rather than 1 cycle) in the retimed netlist.

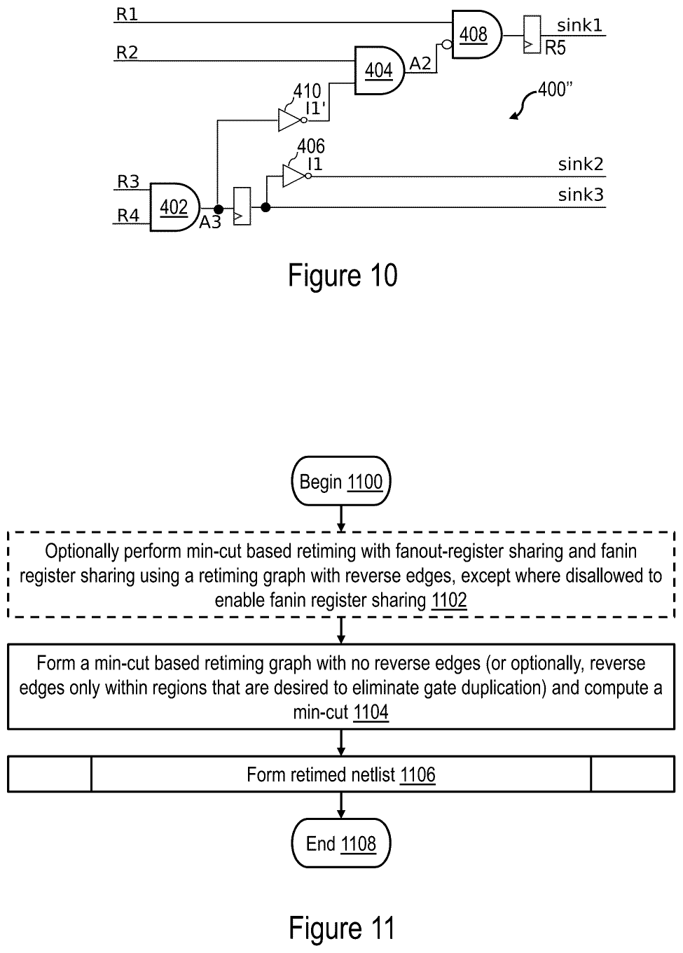

In the technique of min-cut retiming described below with reference to FIG. 11, this prior art altered sequential latency problem is solved by ensuring that the retimed register R5 at sink sink1 does not have a path to the retimed register at net A3. Instead, as shown in retimed netlist 400″ of FIG. 10, gate(s) between the topologically shallower retimed register output and topologically deeper retimed register input are selectively replicated. For example, inverter 406 is replicated to insert inverter 410 between net A3 and an input of AND gate 404. This selective gate duplication allows lagged fanouts of min-cut crossings (between net A3 and sink sink1) to see early logic combinationally driven by original register next-state functions, which need to be clocked once by retimed registers to yield a behaviorally equivalent netlist. The selective gate duplication also allows unlagged fanouts in the sink-side of the cut (between net A3 and sinks sink2 and sink3) to have a path to logic driven by retimed registers, which ensures the retimed netlist is behaviorally equivalent to the original netlist. Because many of the potentially replicated gates fan out to only a single type of sink, in retimed netlist 400″ only two inverters 406 and 410 need be included in retimed netlist 400″. Only a single replication of inverter 406 is needed because AND gates 402 and 404 and sink sink1 are lagged, sinks sink2 and sink3 are not lagged, and only inverter 406 is sampled both by lagged and unlagged logic. The disclosed min-cut based retiming technique is referred to herein as “generalized placement retiming” because the disclosed technique enables more flexible retimed register placement than possible in the prior art, enabling greater reduction in register count.

With reference now to FIG. 11, there is illustrated a high-level logical flowchart of an exemplary technique of min-cut based retiming that achieves a generalized register retiming in accordance with one or more embodiments. The illustrated process can be performed, for example, by processing circuitry 120 through the execution of an EDA tool 150, such as a synthesis tool 156.

The process of FIG. 11 begins at block 1100 and then proceeds to block 1102, which illustrates processing circuitry 120 optionally performing min-cut based retiming with fanout-register sharing (as is conventional) and fanin-register sharing as disclosed herein in FIGS. 8-9. In this min-cut based retiming, processing circuitry 120 implements a retiming graph with reverse edges everywhere except where disallowed to enable fanin register sharing. The processing depicted at block 1102 yields a nearly optimal retimed netlist with no replicated gates.

Following block 1102 if implemented or following block 1100 is block 1102 is omitted, the process of FIG. 11 proceeds to block 1104, which depicts processing circuitry 120 forming a min-cut based retiming graph. In forming the min-cut based retiming graph, processing circuitry 120 refrains from use of reverse edges in at least some regions of the min-cut based retiming graph. In some embodiments or use cases, the min-cut based retiming graph may be formed with no reverse edges at all. Optionally, at block 1104, processing circuitry 120 may selectively insert reverse edges only within a subset of regions of the netlist as desired to preserve a one-to-one relationship between the input netlist and retimed netlist in order to eliminate gate duplication in such regions. Processing circuitry 120 then computes a min-cut by reference to the min-cut based retiming graph.

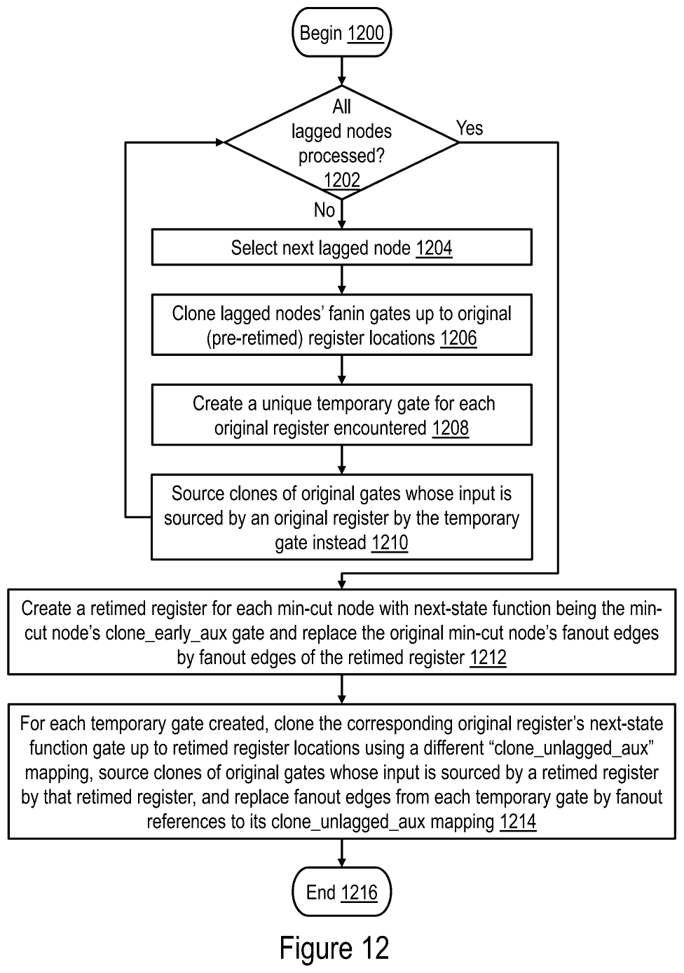

Finally, processing circuitry 120 generates a retimed netlist 164 based on the min-cut. An exemplary technique of forming the retimed netlist at block 1106 is described below with reference to FIG. 12. Following block 1106, the process of FIG. 11 ends at block 1108.

Referring now to FIG. 12, there is depicted a high-level logical flowchart of an exemplary technique of forming a retimed netlist in accordance with one or more embodiments. The illustrated process can be performed at block 1106 of FIG. 11, for example, through execution by processing circuitry 120 of an EDA tool 150, such as a synthesis tool 156. FIG. 12 is not intended to limit the scope of the invention, but instead provides one of possibly multiple ways of forming a behaviorally equivalent retimed netlist based on a min-cut despite suppression of reverse edges. In general, forming a behaviorally equivalent retimed netlist based on the min-cut includes replicating gates along each path of the netlist which crosses the min-cut more than once, removing the original lagged registers in the fanin of this region, inserting a retimed register at the inputs to one replicated copy (e.g., at the topologically shallowest min-cut crossing) and driving unlagged fanout sinks by this replicated copy, and placing a retimed register at the outputs of the non-replicated gates (e.g., at the topologically deepest min-cut crossing) and driving lagged fanout sinks by this retimed register.

The process of FIG. 12 begins at block 1200 and then proceeds block 1202, which illustrates processing circuitry 120 determining whether or not all lagged nodes in the netlist 162 have been processed. In response to an affirmative determination at block 1202, the process passes to block 1212, which is described below. In response to a negative determination at block 1202, processing circuitry 120 selects for processing a next lagged node in the netlist 162 (block 1204). Processing circuitry 120 clones each lagged node's fanin gates up to its original (pre-retimed) register locations (block 1206). Processing circuitry 120 creates a unique temporary gate for each original register encountered in the processing of the lagged node (block 1208). Processing circuitry 120 sources the clones of original gates whose input was sourced by an original register by the temporary gate created at block 1208 instead (block 1210). This mapping from original gates to cloned gates is referred to herein as “clone_early_aux.” Following block 1210, the process returns to block 1202 until all tagged nodes are processed.

Referring now to block 1212, processing circuitry 120 creates a retimed register for each min-cut node in the netlist 162. The next-state function of the retimed register is the min-cut node's clone_early_aux gate. Processing circuitry 120 replaces the original min-cut node's fanout edges by fanout edges of the retimed register.

The process of FIG. 12 proceeds from block 1212 to block 1214, which illustrates that, for each temporary gate created in block 1208, processing circuitry 120 clones the corresponding original register's next-state function gate up to retimed register locations determined at block 1212 using a different “clone_unlagged_aux” mapping. Processing circuitry 120 additionally sources clones of original gates whose input is sourced by a retimed register by that retimed register. Processing circuitry 120 further replaces fanout edges from each temporary gate by fanout references to its clone_unlagged_aux mapping. Following block 1214, the process of FIG. 12 ends at block 1216.

Simple gate-hashing as is commonly used when constructing AND/inverter graph netlists can be used to ensure that no duplicates of functionally identical gates (with same gate type and the same inputs) are created in the retimed netlist during processing at blocks 1206 and 1214. By enabling selective combinational gate duplication, generalized placement retiming allows greater flexibility in retimed register placement, allowing the creation of functionally equivalent retimed netlists with fewer registers than possible in the prior art. Because registers are expensive both in verification (in which unreachable-state enumeration techniques may generally require exponential runtime with respect to register count) and in synthesis (registers tend to have greater area and power consumption than most combinational gates due to clocks and initialization logic, and register count impacts the size and cost of the clock tree), the general reduction in register count has wide-ranging benefits.

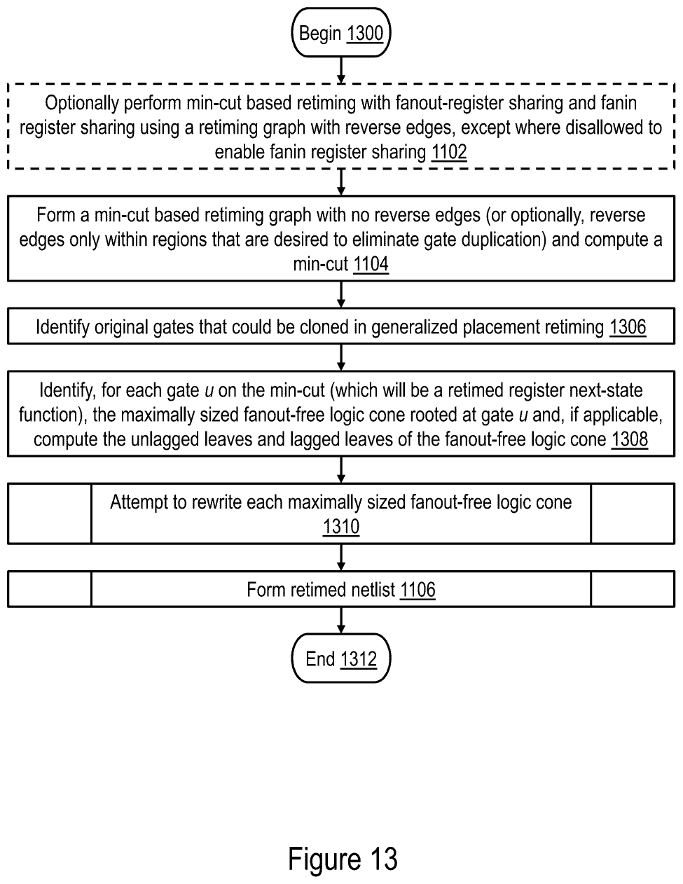

The present disclosure appreciates that retiming netlists by restructuring combinational logic to obtain a functionally equivalent gate implementation results in less gate duplication when performing generalized placement retiming, while still enabling a more flexible retimed register placement and reduced register count. However, through the process of FIG. 13 described below, the present disclosure enables further reduction in gate duplication by rewriting the fanout-free logic cone rooted at a retimed next-state function which will be duplicated to allow placing the retimed register onto a rewritten sub-function (internal gate). The process of FIG. 13 applies to more general logic cones that might not be associative and commutative and minimizes gate duplication while enabling the same reduced retimed register count provided by the generalized placement retiming disclosed in FIGS. 11-12.

With reference now to FIG. 13, there is illustrated a high-level logical flowchart of an exemplary technique of minimizing gate duplication during generalized placement retiming in accordance with one or more embodiments. The illustrated process can be performed, for example, through execution by processing circuitry 120 of an EDA tool 150, such as a synthesis tool 156.

The process of FIG. 13 begins at block 1300 and thereafter proceeds to blocks 1102 and 1104, which are described above with reference to the corresponding steps of FIG. 11 described above. Following block 1104 of FIG. 13, the process proceeds to block 1306, which illustrates processing circuitry 120 identifying original gates that subsequently could be cloned in block 1306 of FIG. 13. Processing circuitry 120 identifies these original gates by marking gates in the fanin of the min-cut and the cut nodes themselves as “cut-fanin” and then marking gates in the fanout of the min-cut as “cut-fanout.” Gates that are marked as both cut-fanin and cut-fanout lie along netlist graph paths that cross the min-cut more than once; those gates that fan out to both lagged and unlagged sinks could be duplicated. Thus, processing circuitry 120 additionally marks gates in the fanin of lagged sinks as “lagged-sink-fanin” and marks gates in the fanin of unlagged sinks as “unlagged-sink-fanin.” Gates having all four markings (i.e., cut-fanin, cut-fanout, lagged-sink-fanin, and unlagged-sink-fanin) could subsequently be duplicated at block 1306 of FIG. 13.

The process proceeds from block 1306 to block 1308. Block 1308 depicts processing circuitry 120 identifying, for each gate u on the min-cut (which will be a retimed register next-state function), the maximally sized fanout-free logic cone rooted at that gate, combining fanin gates that only fan out to the root into the fanout-free logic cone (a process similar to FIG. 9 blocks 910-912, though not limited to combining fanin gates of the same type). If that cone includes a gate with all four markings (which will be duplicated), that cone is a candidate for rewriting in an attempt to minimize the amount of gate duplication. Due to being a fanout-free cone, if any internal gate of that cone is marked with all four markings, then the root gate itself will be marked with all four markings. As further indicated in block 1308, if the leaves of the fanout-free logic cone rooted at u do not include both lagged and unlagged gates or if that fanout-free logic cone has fewer than two leaves, no special handling for the fanout-free logic cone is performed; however, if neither of these conditions applies, processing circuitry 120 computes the set of unlagged leaves UL(u) and the set of lagged leaves L(u) of the fanout-free logic cone.

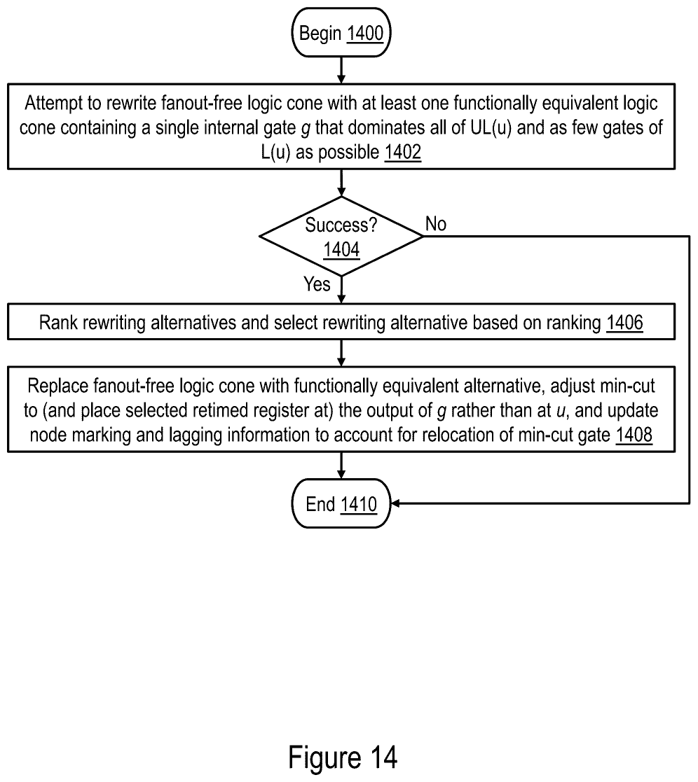

At block 1310, processing circuitry 120 attempts to rewrite each fanout-free logic cone identified at block 1308 with a functionally equivalent logic cone containing a single internal gate g implementing a sub-function which dominates all of UL(u), and as few of L(u) as possible. An exemplary process for implementing block 1310 is described below with reference to FIG. 14. Thereafter, processing circuitry 120 forms a retimed netlist, as described above with reference to block 1106 of FIG. 11 and FIG. 12. The process then terminates at block 1312.

Referring now to FIG. 14, there is depicted a high-level logical flowchart of an exemplary technique of attempting to rewrite a maximally sized fanout-free logic cone in accordance with one or more embodiments. The depicted process can be performed, for example, at block 1310 of FIG. 13 by processing circuitry 120 through execution of an EDA tool 150, such as a synthesis tool 156.

The process of FIG. 14 begins at block 1400 and then proceeds to block 1402, which illustrates processing circuitry 120 attempting to rewrite one of the fanout-free logic cones identified at block 1308 of FIG. 13 with at least one functionally equivalent logic cone containing a single internal gate g that dominates all of UL(u) and as few gates of L(u) as possible. This “function decomposition” can be implemented in a variety of ways. For example, if the fanout-free logic cone is associative and commutative, processing circuitry 120 can rewrite the logic cone by creating one sub-tree g over leaves UL(u) and another sub-tree h over L(u) and the combining these sub-trees with a single gate of relevant type. In this case, no gates will be duplicated and results in similar benefit to that of fanin-register sharing.

If the fanout-free logic cone is not merely associative and commutative, processing circuitry 120 can employ alternative methods to generate functionally equivalent logic. For example, processing circuitry 120 can employ one prior art “dictionary-based rewriting” approaches. These dictionary-based rewriting techniques compute the truth-table of the logic cone and then iterate alternative implementations of that truth-table from a pre-computed dictionary to determine the best alternative. While conventional dictionary-based rewriting tries to optimize only the rewritten logic cone itself, the objective of processing circuitry 120 in the process of FIG. 14 is somewhat different. The objective of the application of a dictionary-based rewriting approach is to atomically optimize the fanout-free logic cone along with its internal duplicated gates, accounting for the number of gates saved by eliminating the need to duplicate the fanin of any separated L(u) leaves. Rewriting alternatives that degrade the rewritten logic cone, yet significantly reduce leaf-fanin duplication, may thus be the best rewriting alternative. (Instead of or in addition to seeking rewriting alternatives within a pre-computed dictionary, there are numerous prior art rewriting techniques that can generate rewriting alternatives directly. For brevity, we will not further elaborate on these prior art techniques.)

At block 1404, processing circuitry 120 determines whether or not the attempt to rewrite the fanout-free logic cone was successful, that is, the processing at block 1402 resulted in generation of at least one functionally equivalent logic cone to the original fanout-free logic cone. In response to a negative determination at block 1404, the process of FIG. 14 passes to block 1410 and terminates. If, however, processing circuitry 120 makes an affirmative determination at block 1404, processing circuitry 120 ranks the alternative functionally equivalent logic cones generated at block 1402 and selects one of the alternative functionally equivalent logic cone based on the ranking (block 1406). For example, processing circuitry 120 can rank the alternative functionally equivalent logic cones by counting the total number of gates in the rewritten logic cone plus the total number of gates within the rewritten logic cone that will be duplicated (in the fanout of both L(u) and UL(u)) minus the total number of gates in the fanout-free logic cone rooted at each marked-for-duplication L(u) leaf which has been separated to no longer appear in the fanin of g. In this example, processing circuitry 120 selects the alternative functionally equivalent logic cone having the fewest number of gates.

As an example of the processing at block 1406, consider the three following implementations for a fanout-free logic cone rooted at gate u with leaves a, b, c, and d:

$$( a \& b ) \vert ( a \& c ) \vert \begin{matrix}( c \& d ) & // Implementation 1\end{matrix} \\ ( a \& ( b \vert c ) ) \vert \begin{matrix}( c \& d ) & // Implementation 2\end{matrix} \\ ( a \& ( a \vert d ) ) \vert \begin{matrix}( a \& b ) & // Implementation 3\end{matrix}$$

Further, consider a generalized placement retiming solution in which the min-cut includes u, such that UL(u)={c,d} and L(u)={a,b}. When considering Implementation 1, gate g=((a&c)|(c&d)) allows separating leaf c, while duplicating gates ( . . . )|((a&c)|(c&d)). When considering Implementation 2, no gate is a candidate for g aside from u itself; thus, no leaves are separated and (a&(b|c))|( . . . ) would be duplicated. Implementation 3 is potentially the most attractive alternative because g= [symbol] c&(a|d)) allows separating leaf b, and only duplicates (c&(a|d))|( . . . ).

At block 1408, processing circuitry 120 replaces the original fanout-free logic cone with the alternative functionally equivalent logic cone. In addition, processing circuitry 120 adjusts the min-cut in the retiming graph to the corresponding internal gate g instead of original location at node u. Based on the relocation of the cut gate, processing circuitry 120 also updates the markings (i.e., cut-fanin, cut-fanout, lagged-sink-fanin, and unlagged-sink-fanin) and lagging information of the rewritten gates. Thereafter, the process of FIG. 14 ends at block 1410.

A technical challenge with retiming netlists is that the sizes of retimeable regions are often limited, precluding the retimability of certain netlist gates. For example, if a retiming of a netlist does not permit “peripheral retiming” in which registers can be borrowed from primary inputs, all gates in the combinational fanout of primary inputs are unretimeable and are typically suppressed from the retiming graph. Additionally, gates on the boundary between retimeable (e.g., in the fanout of a register) and unretimeable (e.g., in the combinational fanout of primary inputs) are conventionally modeled as sinks in the retiming graph, similar to primary outputs. This modeling restricts retiming processing in that registers may be moved from their original locations up to, but not beyond, this boundary. Further, in some designs, black-boxed components (e.g., IP blocks) or complex components such as random access memory (RAM) arrays might be considered unretimeable. In at least some conventional retiming processing, the inputs of black-boxed or complex components are treated as primary outputs/sinks, and the combinational fanout of their outputs are treated as unretimeable, similar to the primary inputs discussed above. In addition, when retiming a netlist having multiple clock domains, retiming is conventionally performed independently within each netlist region comprising registers with the same clock, and gates that are combinationally driven by multiple clock domains are considered unretimeable. The present disclosure appreciates that it would be useful and desirable to maximize the size of retimeable netlist regions, enabling greater flexibility in retimed register placement, and thus greater reductions via min-area retiming.

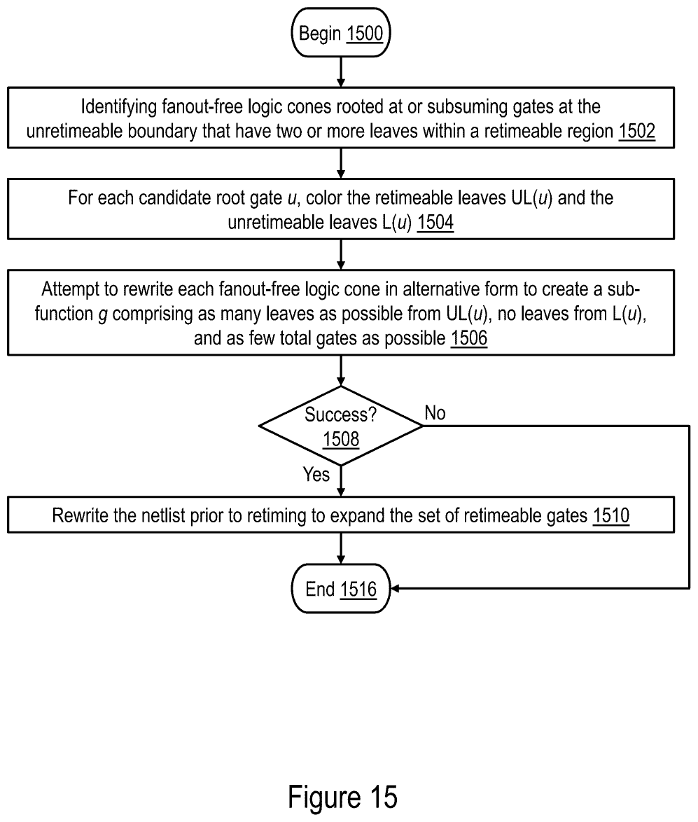

With reference now to FIG. 15, there is illustrated a high-level logical flowchart of an exemplary technique for rewriting a netlist to maximize the size of retimeable regions in accordance with one or more embodiments. The illustrated process can be performed, for example, by processing circuitry 120 through execution of an EDA tool 150, such as a synthesis tool 156. The illustrated process can be performed in some implementations as a preprocessing step prior to creating a retimed netlist, as depicted at block 1106 of FIGS. 11 and 13.

The process of FIG. 15 begins at block 1500 and then proceeds to block 1502, which illustrates processing circuitry 120 identifying fanout-free logic cones rooted at or subsuming gates at the unretimeable boundary that have two or more leaves within a retimeable region. These fanout-free logic cones, each of which has a respective root gate u, form a set of candidate logic cones to be rewritten. For each candidate's root gate u, processing circuitry 120 colors the retimeable leaves UL(u) and the unretimeable leaves L(u) (block 1504). Processing circuitry 120 then attempts to rewrite each candidate logic cone in an alternative form, specifically trying to create a sub-function g comprising as many leaves as possible from UL(u), no leaves from L(u), and as few total gates as possible (block 1506). In at least some embodiments, at block 1506, processing circuitry 120 can employ a process similar to that depicted in FIG. 14 and described above to develop the alternative logic cones.

At block 1508, processing circuitry 120 determines if the attempt to rewrite the fanout-free logic cones in alternative form at block 1506 was successful, that is, if, for at least one fanout-free logic cone identified at block 1502, an alternative logically equivalent logic cone was determined in which g includes more leaves from UL(u) than the original logic structure. In response to a negative determination at block 1508, the process of FIG. 15 ends at block 1516. If, however, processing circuitry 120 makes an affirmative determination at block 1508, processing circuitry 120 rewrites the netlist 162 to expand the set of retimeable gates by replacing each fanout-free logic cone for which a superior logically equivalent alternative was found with its alternative (block 1510). The process of FIG. 15 then ends at block 1516.

After a netlist 162 is rewritten in accordance with the technique disclosed in FIG. 15, processing circuitry 120 can perform retiming as discussed above. After retiming, processing circuitry 120, through execution of an EDA tool 150, can optionally attempt to restore some original logic structure within a retimed netlist 164 where possible, e.g., if the retimed netlist 164 did not leverage a particular logic cone alternative.

For example, consider a netlist with primary inputs i1, i2, . . . and registers r1, r2, . . . and output o1. If o1<=(r1 & i1) & (r2 & i2) and peripheral retiming is disabled, no retiming of this logic is possible because every AND gate is combinationally driven by primary inputs. Gates (r1 & i1) and (r2 & i2) are both on the unretimeable boundary. However, because o1 is a fanout-free cone, the technique disclosed in FIG. 15 can be employed to rewrite this netlist to o1<=(i1 & i2) & (r1 & r2), allowing a single retimed register to be moved across the latter AND gate (r1 & r2).

As has been described, according to one or more embodiments, a technique of min-cut based retiming of a netlist includes forming a min-cut based retiming graph based on a netlist of a circuit design. Forming the min-cut based retiming graph includes refraining from use of reverse edges in at least some regions of the min-cut based retiming graph. The technique further includes computing a min-cut of the circuit design based on the min-cut based retiming graph, where the min-cut crosses at least one graph path multiple times in a particular region of the min-cut based retiming graph. A behaviorally equivalent retimed netlist is then formed based on the min-cut, including in the particular region. This technique, which can be implemented, for example, as a method, a computer program product, or a data processing system, provide the performance benefits of min-cut based retiming while avoiding formation of an invalid retimed netlist.

According to one or more embodiments, a technique of min-cut based retiming includes modeling an associative-commutative logic cone in a netlist as a single retiming graph node and suppressing reverse edges from the retiming graph node to its fanin gates. Based on placement of the min-cut at the retiming graph node, the behaviorally equivalent retimed netlist includes rewriting the associative-commutative logic cone into separate lagged and unlagged sub-functions and placing a retimed state-holding element between the lagged and unlagged sub-functions. This technique implements fanin register sharing with min-cut based retiming.

According to one or more embodiments, a technique of min-cut based retiming includes forming an associative-commutative logic cone modeled by a single retiming graph node to be of maximal fanout-free size. Prior to forming a min-cut based retiming graph, one or more state-holding elements partitioning two identical-function logic cones are backward retimed. This technique enables fewer and larger associative-commutative logic cones to be formed.

According to one or more embodiments, the min-cut based retiming graph includes no reverse edges outside associative-commutative logic cones. By restricting reverse edges in the retiming graph, this technique allows forming superior retimed netlists than possible using prior art by reducing the number of state-holding elements in the retimed netlist.

In one or more embodiments, forming a retimed netlist based on the min-cut includes replicating gates along each path of the netlist that crosses the min-cut more than once, removing the original lagged state-holding elements in the fanin of this region, inserting a retimed state-holding element at the inputs to one replicated gate and driving unlagged fanout sinks by this replicated copy, and placing a retimed state-holding element at the outputs of the non-replicated gates and driving lagged fanout sinks by this retimed state-holding element. This netlist retiming technique results in a valid retimed netlist having equivalent function and fewer state-holding elements.

In one or more embodiments, a min-cut based retiming technique includes reducing a number of the replicated gates. Reducing the number of replicated gates includes identifying a fanout-free logic cone rooted at a topologically-deepest crossing of the min-cut, determining an alternative implementation of the fanout-free logic cone, where the alternative implementation includes a sub-function internal gate that dominates all unlagged inputs of the fanout-free logic cone and a minimum set of lagged inputs, replacing the fanout-free logic cone with the alternative implementation, and relocating the min-cut from an output of the fanout-free logic cone to the internal gate of the alternative implementation.

In one or more embodiments, prior to performing min-cut based retiming of the netlist, the netlist is rewritten to enlarge a size of a retimeable region in the netlist. Expanding the retimeable region enables elimination from the netlist of additional state-holding elements.

In one or more embodiments, a technique for rewriting a netlist to enlarge a size of a retimeable region of the netlist includes identifying a fanout-free logic cone including gates at a boundary between the retimeable region and an unretimeable region, determining, for the fanout-free logic cone, an equivalent alternative sub-function including as many leaves as possible from the retimeable region and no leaves from the unretimeable region, and, responsive to the sub-function including more leaves in the retimeable region than the fanout-free logic cone, rewriting the netlist to include the sub-function. This technique enables the boundary of the retimeable region to be expanded efficiently.

In one or more embodiments, after rewriting the netlist to enlarge the size of a retimeable region, min-cut based retiming of the netlist is performed. Rewriting the netlist to enlarge the retimeable region prior to retiming the netlist allows the min-cut based retiming to operate on a greater portion of the netlist, resulting in greater reductions in state-holding elements.

While the present invention has been particularly shown as described with reference to one or more preferred embodiments, it will be understood by those skilled in the art that various changes in form and detail may be made therein without departing from the spirit and scope of the invention.

The following definitions are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, system or apparatus that comprises a list of elements is not necessarily limited to only those elements but can include other elements not expressly listed or inherent to such composition, mixture, process, method, article, system or apparatus.

Additionally, the term “exemplary” is used herein to mean “serving as one example, instance or illustration.” Any embodiment or design described herein as “exemplary” is not necessarily to be construed as preferred or advantageous over other embodiments or designs. The terms “at least one” and “one or more” shall be understood to include any integer number greater than or equal to one, and the term “plurality” shall be understood to include any integer number greater than or equal to two. The term “coupled” shall include both indirect connection and a direct connection, unless specified otherwise in a particular case. The terms “about,” “substantially,” “approximately,” and variations thereof, are intended to include the degree of error associated with measurement of the particular quantity based upon the equipment available at the time of filing the application. For example, “about”can include a range of ±10% or ±5%, or ±2% of a given value.

The figures described herein and the written description of specific structures and functions are not presented to limit the scope of what Applicants have invented or the scope of the appended claims. Rather, the figures and written description are provided to teach any person skilled in the art to make and use the inventions for which patent protection is sought. Those skilled in the art will appreciate that not all features of a commercial embodiment of the inventions are described or shown for the sake of clarity and understanding. For the sake of brevity, conventional techniques related to making and using aspects of the invention(s) may or may not be described in detail herein, and many conventional implementation details are only mentioned briefly or are omitted entirely. Persons of skill in this art will also appreciate that the development of an actual commercial embodiment incorporating aspects of the present inventions will require numerous implementation-specific decisions to achieve the developer's ultimate goal for the commercial embodiment. Such implementation-specific decisions may include, and likely are not limited to, compliance with system-related, business-related, government-related and other constraints, which may vary by specific implementation, location and from time to time. While a developer's efforts might be complex and time-consuming in an absolute sense, such efforts would be, nevertheless, a routine undertaking for those of skill in this art having benefit of this disclosure. It must be understood that the inventions disclosed and taught herein are susceptible to numerous and various modifications and alternative forms. Lastly, the use of a singular term, such as, but not limited to, “a” is not intended as limiting of the number of items.

What is claimed is:

1. A computer-implemented method of min-cut based retiming of a netlist, the method comprising:
processing circuitry of a data processing system, based on a netlist of a circuit design, forming a min-cut based retiming graph, wherein forming the min-cut based retiming graph includes refraining from use of reverse edges in at least some regions of the min-cut based retiming graph;
the processing circuitry computing a min-cut of the circuit design based on the min-cut based retiming graph, wherein the min-cut crosses at least one graph path multiple times in a particular region of the min-cut based retiming graph; and
based on the min-cut, the processing circuitry forming a behaviorally equivalent retimed netlist, including in the particular region.

2. The method of claim 1, further comprising:
modeling an associative-commutative logic cone in the netlist as a single retiming graph node; and
suppressing reverse edges from the retiming graph node to its fanin gates;
wherein, based on placement of the min-cut at the retiming graph node, forming the behaviorally equivalent retimed netlist includes:
rewriting the associative-commutative logic cone into separate lagged and unlagged sub-functions and placing a retimed state-holding element between the lagged and unlagged sub-functions.

3. The method of claim 2, further comprising:
forming the associative-commutative logic cone modeled by the single retiming graph node to be of maximal fanout-free size, and
prior to forming the min-cut based retiming graph, backward retiming one or more state-holding elements partitioning two identical-function logic cones, such that fewer and larger associative-commutative logic cones can be formed.

4. The method of claim 1, wherein forming the min-cut based retiming graph includes forming the min-cut based retiming graph without reverse edges outside associative-commutative logic cones.

5. The method of claim 1, wherein forming a retimed netlist based on the min-cut includes:
creating replicated gates along paths of the min-cut based retiming graph that cross the min-cut more than once;
placing a first retimed state-holding element at a topologically shallowest min-cut crossing, wherein the first retimed state-holding element corresponds to an original state-holding element in the netlist, and wherein the first retimed state-holding element sources a first copy of the replicated gates;
sourcing a second copy of the replicated gates by a next-state function of the original state-holding element;
connecting unlagged sinks to the first copy of the replicated gates; and
connecting lagged sinks to a second retimed state-holding element placed at an output of the second copy of the replicated gates.

6. The method of claim 5, further comprising reducing a number of the replicated gates, wherein the reducing includes:
identifying a fanout-free logic cone rooted at a topologically-deepest crossing of the min-cut;
determining an alternative implementation of the fanout-free logic cone, wherein the alternative implementation includes a sub-function internal gate that dominates all unlagged inputs of the fanout-free logic cone and a minimum set of lagged inputs;
replacing the fanout-free logic cone with the alternative implementation; and
relocating the min-cut from an output of the fanout-free logic cone to the internal gate of the alternative implementation.

7. The method of claim 1, further comprising:
prior to performing min-cut based retiming of the netlist, rewriting the netlist to enlarge a size of a retimeable region in the netlist.

8. The method of claim 7, wherein rewriting the netlist includes:
identifying a fanout-free logic cone including gates at a boundary between the retimeable region and an unretimeable region;
determining, for the fanout-free logic cone, an equivalent alternative sub-function including as many leaves as possible from the retimeable region and no leaves from the unretimeable region; and
responsive to the sub-function including more leaves in the retimeable region than the fanout-free logic cone, rewriting the netlist to include the sub-function.

9. A method for rewriting a netlist to enlarge a size of a retimeable region, the method comprising:
identifying a fanout-free logic cone including gates at a boundary between the retimeable region and an unretimeable region;
determining, for the fanout-free logic cone, an equivalent alternative sub-function including as many leaves as possible from the retimeable region and no leaves from the unretimeable region; and
responsive to the sub-function including more leaves in the retimeable region than the fanout-free logic cone, rewriting the netlist to include the sub-function.

10. A computer program product, comprising:
a storage device; and
program code stored within the storage device and executable by processing circuitry of a data processing system to cause the data processing system to perform min-cut based retiming of a netlist, wherein min-cut based retiming of the netlist includes:
based on a netlist of a circuit design, forming a min-cut based retiming graph, wherein forming the min-cut based retiming graph includes refraining from use of reverse edges in at least some regions of the min-cut based retiming graph;
computing a min-cut of the circuit design based on the min-cut based retiming graph, wherein the min-cut crosses at least one graph path multiple times in a particular region of the min-cut based retiming graph; and
based on the min-cut, forming a behaviorally equivalent retimed netlist, including in the particular region.

11. The computer program product of claim 10, wherein the program code is further executable by the processing circuitry to cause the data processing system to perform:
modeling an associative-commutative logic cone in the netlist as a single retiming graph node; and
suppressing reverse edges from the retiming graph node to its fanin gates;
wherein, based on placement of the min-cut at the retiming graph node, forming the behaviorally equivalent retimed netlist includes:
rewriting the associative-commutative logic cone into separate lagged and unlagged sub-functions and placing a retimed state-holding element between the lagged and unlagged sub-functions.

12. The computer program product of claim 11, wherein the program code is further executable by the processing circuitry to cause the data processing system to perform:
forming the associative-commutative logic cone modeled by the single retiming graph node to be of maximal fanout-free size, and
prior to forming the min-cut based retiming graph, backward retiming one or more state-holding elements partitioning two identical-function logic cones, such that fewer and larger associative-commutative logic cones can be formed.

13. The computer program product of claim 10, wherein forming the min-cut based retiming graph includes forming the min-cut based retiming graph without reverse edges outside associative-commutative logic cones.

14. The computer program product of claim 10, wherein forming a retimed netlist based on the min-cut includes:
creating replicated gates along paths of the min-cut based retiming graph that cross the min-cut more than once;
placing a first retimed state-holding element at a topologically shallowest min-cut crossing, wherein the first retimed state-holding element corresponds to an original state-holding element in the netlist, and wherein the first retimed state-holding element sources a first copy of the replicated gates;
sourcing a second copy of the replicated gates by a next-state function of the original state-holding element;
connecting unlagged sinks to the first copy of the replicated gates; and
connecting lagged sinks to a second retimed state-holding element placed at an output of the second copy of the replicated gates.

15. The computer program product of claim 14, wherein the program code is further executable by the processing circuitry to cause the data processing system to perform reducing a number of the replicated gates, wherein the reducing includes:
identifying a fanout-free logic cone rooted at a topologically-deepest crossing of the min-cut;
determining an alternative implementation of the fanout-free logic cone, wherein the alternative implementation includes a sub-function internal gate that dominates all unlagged inputs of the fanout-free logic cone and a minimum set of lagged inputs;
replacing the fanout-free logic cone with the alternative implementation; and
relocating the min-cut from an output of the fanout-free logic cone to the internal gate of the alternative implementation.

16. The computer program product of claim 10, wherein the program code is further executable by the processing circuitry to cause the data processing system to perform:
prior to performing min-cut based retiming of the netlist, rewriting the netlist to enlarge a size of a retimeable region in the netlist.

17. The computer program product of claim 16, wherein rewriting the netlist includes:
identifying a fanout-free logic cone including gates at a boundary between the retimeable region and an unretimeable region;
determining, for the fanout-free logic cone, an equivalent alternative sub-function including as many leaves as possible from the retimeable region and no leaves from the unretimeable region; and
responsive to the sub-function including more leaves in the retimeable region than the fanout-free logic cone, rewriting the netlist to include the sub-function.

18. A computer program product, comprising:
a storage device; and
program code stored within the storage device and executable by processing circuitry of a data processing system to cause the data processing system to perform rewriting a netlist to enlarge a size of a retimeable region, wherein rewriting the netlist includes:
identifying a fanout-free logic cone including gates at a boundary between the retimeable region and an unretimeable region;
determining, for the fanout-free logic cone, an equivalent alternative sub-function including as many leaves as possible from the retimeable region and no leaves from the unretimeable region; and
responsive to the sub-function including more leaves in the retimeable region than the fanout-free logic cone, rewriting the netlist to include the sub-function.

19. A data processing system, comprising:
processing circuitry; and
a storage device coupled to the processor set, wherein the storage device includes program code executable by the processing circuitry to cause the data processing system to perform:
based on a netlist of a circuit design, forming a min-cut based retiming graph, wherein forming the min-cut based retiming graph includes refraining from use of reverse edges in at least some regions of the min-cut based retiming graph;
computing a min-cut of the circuit design based on the min-cut based retiming graph, wherein the min-cut crosses at least one graph path multiple times in a particular region of the min-cut based retiming graph; and
based on the min-cut, forming a behaviorally equivalent retimed netlist, including in the particular region.

20. The data processing system of claim 19, wherein the program code is further executable by the processing circuitry to cause the data processing system to perform:
modeling an associative-commutative logic cone in the netlist as a single retiming graph node; and
suppressing reverse edges from the retiming graph node to its fanin gates;
wherein, based on placement of the min-cut at the retiming graph node, forming the behaviorally equivalent retimed netlist includes:
rewriting the associative-commutative logic cone into separate lagged and unlagged sub-functions and placing a retimed state-holding element between the lagged and unlagged sub-functions.

21. The data processing system of claim 20, wherein the program code is further executable by the processing circuitry to cause the data processing system to perform:
forming the associative-commutative logic cone modeled by the single retiming graph node to be of maximal fanout-free size, and
prior to forming the min-cut based retiming graph, backward retiming one or more state-holding elements partitioning two identical-function logic cones, such that fewer and larger associative-commutative logic cones can be formed.

22. The data processing system of claim 19, wherein forming the min-cut based retiming graph includes forming the min-cut based retiming graph without reverse edges outside associative-commutative logic cones.

23. The data processing system of claim 19, wherein forming a retimed netlist based on the min-cut includes:
creating replicated gates along paths of the min-cut based retiming graph that cross the min-cut more than once;
placing a first retimed state-holding element at a topologically shallowest min-cut crossing, wherein the first retimed state-holding element corresponds to an original state-holding element in the netlist, and wherein the first retimed state-holding element sources a first copy of the replicated gates;
sourcing a second copy of the replicated gates by a next-state function of the original state-holding element;
connecting unlagged sinks to the first copy of the replicated gates; and
connecting lagged sinks to a second retimed state-holding element placed at an output of the second copy of the replicated gates.

24. The data processing system of claim 23, wherein the program code is further executable by the processing circuitry to cause the data processing system to perform reducing a number of the replicated gates, wherein the reducing includes:
identifying a fanout-free logic cone rooted at a topologically-deepest crossing of the min-cut;
determining an alternative implementation of the fanout-free logic cone, wherein the alternative implementation includes a sub-function internal gate that dominates all unlagged inputs of the fanout-free logic cone and a minimum set of lagged inputs;
replacing the fanout-free logic cone with the alternative implementation; and
relocating the min-cut from an output of the fanout-free logic cone to the internal gate of the alternative implementation.

25. The data processing system of claim 19, wherein the program code is further executable by the processing circuitry to cause the data processing system to perform:
prior to performing min-cut based retiming of the netlist, rewriting the netlist to enlarge a size of a retimeable region in the netlist.
